(19) United States
(12) Patent Application Publication
(10) Pub. No.: US 2006/0168490 A1
(43) Pub. Date: Jul. 27, 2006

(54) Apparatus and method of controlling test modes of a scannable latch in a test scan chain

(76) Inventors: James Arthur McCormack, Boston, MA (US); Todd Mellinger, Fort Collins, CO (US); Peter David Maroni, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/041,584

(22) Filed: Jan. 24, 2005

(51) Int. Cl. G01R 31/28

(52) U.S. Cl. 714/726

(57) ABSTRACT

Apparatus for controlling an operational test mode of a scannable latch in a test scan chain, the scannable latch comprising a scan latch and a functional latch coupled thereto, comprises: first circuit for gating a clock signal to the functional latch, the functional latch being responsive to the gated clock signal to capture operational data, the first circuit including an input for controlling the gating operations thereof; and second circuit governed by a selection signal to apply a selected one of a first signal and second signal to the input of the first circuit to control the scannable latch between controllable and observable test modes of operation.

### BACKGROUND

Today's electrical systems are generally embedded in very large scale integrated (VLSI) circuits which contain hundreds of thousands if not millions of electrical cells. Usually, these cells are grouped into functional units which may include both combinational logic and sequential logic comprised of clocked memory elements referred to as functional latches. After fabrication, each VLSI circuit is tested to check the functionality of its logic circuits and the interconnections thereof. In order to expedite this process, the VLSI circuits are fabricated with built-in test (BIT) circuits, which may be in the form of JTAG scan chains, for example. JTAG scan chain circuits are constructed and operated by a test access process (TAP) controller in accordance with the IEEE standard 1149.1.

Typically, the latches of a functional unit within a VLSI circuit are interfaced to corresponding scan latches in a boundary scan chain as illustrated by way of example in the block diagram schematic of FIG. 1. More specifically, a plurality of scan latches SL1, . . . , SLN of a test scan chain are controlled by the TAP controller 10 to test the functional logic unit 12 shown within the dashed lines. Each scan latch SL1, . . . , SLN is coupled to a corresponding functional latch FL1, . . . , FLN in unit 12 by signal lines S1, . . . , SN, respectively. Test bit patterns are supplied by the TAP controller 10 to the scan latches SL1, . . . , SLN over a serial bus 14 which is daisy chained among the serial in (SI) and serial out (SO) ports of the latches SL1, . . . , SLN. The serial bus 14 begins and ends in the TAP controller 10 so that resultant test data may be read from the scan latches SL1, . . . , SLN to the TAP controller 10 thereover.

In operation, the TAP controller 10 may be operated by standardized JTAG bus signals TCK, TDI, TDO, TRST, and TMS to control the flow of test and resultant bit pattern date over the serial bus 14 through control signals comprising Shift, Update and Write provided to the scan latches SL1, . . . , SLN over a parallel bus 16. The scan latches SL1, . . . , SLN may exchange test data with their respectively corresponding functional latches FL1, . . . , FLN of unit 12 via respective signal lines S1, . . . , SN using a master or chip clock MCK which may be generated by a clock generator 18, for example, under control of the TAP controller 10. Each combination of a scan and functional latch is commonly referred to as a scannable latch in the test scan chain. Accordingly, the TAP controller 10 may introduce test data to each scannable latch (controllability mode) or read the resultant test data from a scannable latch (observability mode), but not both, utilizing the clock MCK and control signals of bus 16. From the resultant bit pattern, the TAP controller 10 may determine a failure in the functionality and/or circuit interconnection of the unit 12. Note that the scan portion SL1, . . . , SLN will not exchange data unless Read or Write is toggled. When Read toggles, data is transferred from a functional latch FL to a scan latch SL via respect signal lines S, and when Write toggles, data is transferred from a scan latch SL to a functional latch FL via respective signal lines S.

An exemplary scannable latch combination circuit suitable for use in the embodiment of FIG. 1 is shown in the block diagram schematic of FIG. 2. Referring to FIG. 2, a scan latch 20 which is exemplary of the latches in the scan chain SL1, . . . , SLN is coupled to its corresponding functional latch 22 in the functional logic unit 12 by way of two signal lines fb and in1, for example. The functional latch 22 may be a level sensitive latch which will be described in greater detail herein below. The scan latch 20 is also coupled to the serial bus 14 and to the control signals Shift, Update and Write of the parallel bus 16. Under functional operation, data is provided to an input port 24 of the functional latch 22 over a signal line designated as “in”. A gate 26 may be provided in the signal line “in” to buffer the data signal. A latch clock NCK, which may be derived from the master clock MCK (see FIG. 1), for example, controls the capturing of data at the port 24 by the latch 22 as will become more evident from the description infra. In the present embodiment, the clock NCK is derived from the master clock MCK through a clock driver circuit 28 which enables the clock NCK to be pulsed or fired.

Accordingly, when the clock NCK goes to a logic one or high, the latch 22 is open to permit data at port 24 to enter the latch 22, and when the clock NCK goes to a logic zero or low, the entered data is captured by the functional latch 22 at the output port 30. While the present level sensitive latches use the positive level (i.e. logic high or “1”) of MCK to open, it is understood that other type level sensitive latches may use the negative level (i.e. logic low or “0”) to open. In either case, without the enable signal being at logic high or one, the output of the clock driver 28 or NCK is held low regardless of the logic state of MCK.

Applicants have discovered certain limitations of assemblies of the types described above with reference to FIGS. 1 and 2 as discussed below. Currently, a single scannable latch of a test scan chain may not be both observable and controllable because the clock driver circuit 28 of each is either set up for the observability test mode of operation or the controllability test mode of operation, but not both. When a scannable latch is set up for observability mode operation, an enable (en) input of the clock driver 28 is coupled to a supply voltage V_{DD}. This enables the NCK clock to be pulsed, i.e. go from low to high and back to low, commensurate with the master clock MCK. Accordingly, with each pulse of the latch clock NCK, the functional latch 22 captures data at its port 24. At certain captures, the signal Update may be pulsed to transfer the captured data of latch 22 over signal lines in1 and fb to the scan latch 20. Thereafter, using the Shift signal, the data of scan latch 20 may be shifted out over serial bus 14 back to the TAP controller 10 (see FIG. 1) for analysis. In this manner, the captured data of the latch 22 may be observed at certain times by the TAP controller 10.

When a scannable latch is set up for controllability mode operation, the en input of the clock driver 28 is coupled to a signal which is low when data is being scanned via serial bus 14 into or through the latch 20. As a result, the latch clock NCK is forced low and disabled during this period of scan chain testing. Accordingly, test data may be scanned into the latch 20 via the serial bus 14 using the Shift signal, for example, and then, written into the functional latch 22 over signal lines fb and in1 by pulsing the Write signal which controls the data at the output port 30 thereof without interference of the latch clock NCK.

If a scannable latch set up for observable operation attempts to write data into the latch 22, the clock NCK would continue firing during the write operations. Thus, test data written into the functional latch 22 from the scan latch 20 would be overwritten by the input data at port 24 at the next pulse of clock NCK. Likewise, if a scannable latch is set up for controllable operation, the latch clock NCK is disabled during test data scanning, and as a result, data at port 24 may not be captured by the latch 22 during this time period. Therefore, functional operations of latch 22 in response to test data may not be properly observed.

### SUMMARY

In accordance with one aspect of the present invention, apparatus for controlling an operational test mode of a scannable latch in a test scan chain, the scannable latch comprising a scan latch and a functional latch coupled thereto, comprises: first circuit for gating a clock signal to the functional latch, the functional latch being responsive to the gated clock signal to capture operational data, the first circuit including an input for controlling the gating operations thereof; and second circuit governed by a selection signal to apply a selected one of a first signal and second signal to the input of the first circuit to control the scannable latch between controllable and observable test modes of operation.

### BRIEF DESCRIPTION OF THE DRAWINGS

FIG. 1 is a block diagram schematic of an exemplary system for scan chain testing of a functional logic unit.

FIG. 2 is a block diagram schematic of an exemplary scan latch/functional latch combination suitable for use as a scannable latch.

FIGS. 3A and 3B are, in composite, a circuit schematic of an exemplary scan latch.

FIG. 4 is a circuit schematic of an exemplary level sensitive functional latch.

FIG. 5 is a block diagram schematic of an exemplary scannable latch for scan chain testing.

FIG. 6 is a block diagram schematic of an exemplary system for scan chain testing of a functional logic unit.

FIG. 7 is a flow chart of an embodiment of a method of controlling an operational test mode of a scannable latch.

### DETAILED DESCRIPTION OF THE INVENTION

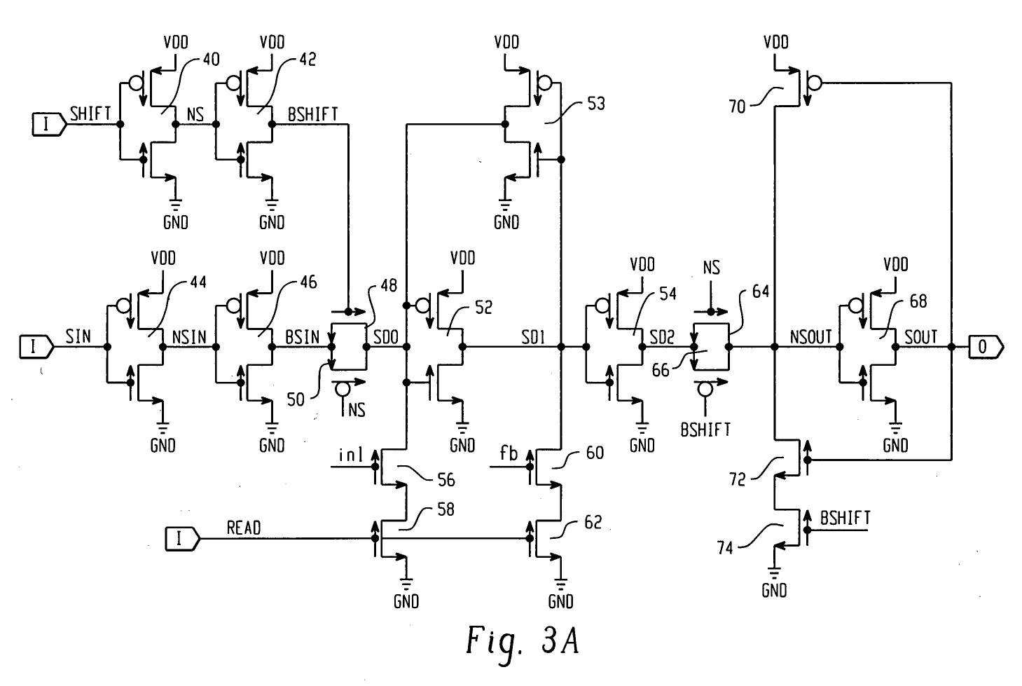

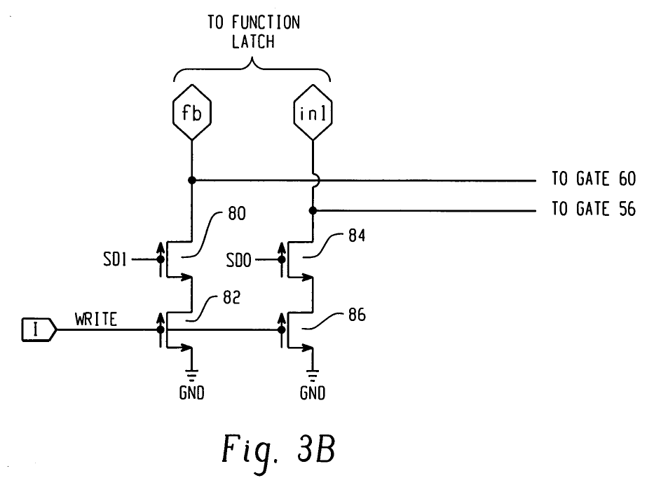

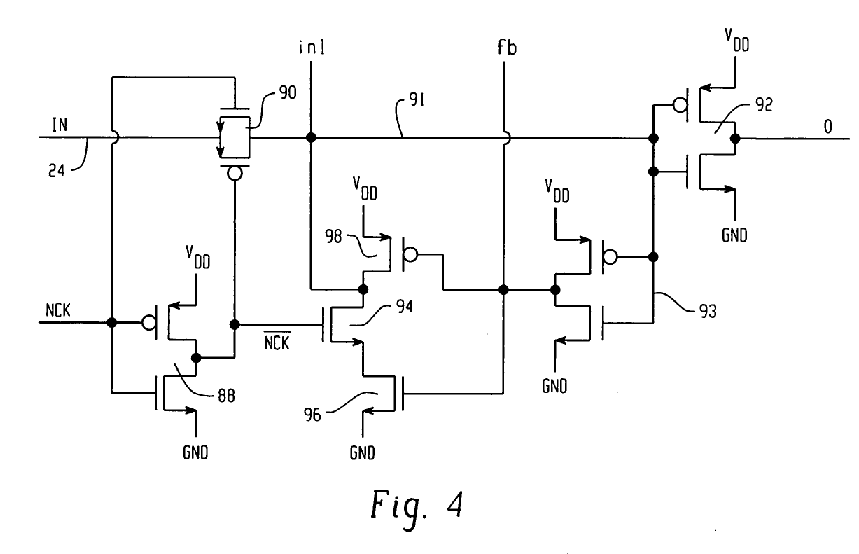

To better understand the operation of the present embodiments, circuit schematics of exemplary scan and functional latches are depicted in FIGS. 3A, 3B and 4, respectively. These exemplary circuits are suitable for use in the present embodiments which will be described herein below. Hereinafter, FIGS. 3A and 3B will be referred to compositely as FIG. 3. The exemplary scan latch circuit of FIG. 3 is comprised of NMOS and PMOS transistors as well as complementary metal oxide semiconductor (CMOS) transistor pairs. All of the CMOS pairs of the circuit are coupled between the supply buses V_{DD} and ground GND. Referring to FIG. 3, the SHIFT signal is coupled through a CMOS pair 40 to produce the signal ns which is coupled through another CMOS pair 42 to produce the signal bshift. Similarly, the scan in (sin) signal is coupled through a CMOS pair 44 to produce the signal nsin which is coupled through another CMOS pair 46 to produce the signal bsin. The signal bsin is coupled through the parallel channels of a pair of NMOS and PMOS transistors, 48 and 50, respectively, that are coupled source- to-source and drain-to-drain. The NMOS transistor 48 is gated by the signal bshift and the PMOS transistor 50 is gated by the complementary signal ns. The drain side of the transistor pair 48 and 50 effects the signal sd0 which is coupled through a CMOS pair 52 to produce the signal sd1 which is coupled through another CMOS pair 54 to produce the signal sd2. The signal sd1 is also coupled to the gates of another CMOS pair 53, the out put of which being coupled back to the signal sd0.

Note that transistors 52 and 53 allow sd0 and sd1 to hold a “latched” state when transistors 48 and 50 are “closed”. In addition, when transistors 48 and 50 are “open”, sd0 goes to the state of signal bsin. Likewise, when transistors 64 and 66 are “open”, nsout goes to the state of sd2. Transistor pair 48 and 50 operate complementary to transistor pair 64 and 66 (i.e. when one pair of transistors are open, the pair is closed).

The signal sd0 is also coupled to ground GND through a pair of series connected NMOS transistors 56 and 58, transistor 56 being gated by the signal in1 and transistor 58 being gated by the signal UPDATE. Likewise, the signal sd1 is also coupled to GND through a pair of series connected NMOS transistors 60 and 62, transistor 60 being gated by the signal fb and transistor 62 being gated by the signal UPDATE. Signal sd2 is coupled through the parallel channels of a pair of NMOS and PMOS transistors, 64 and 66, respectively, that are coupled source-to-source and drain-to-drain. The NMOS transistor 64 is gated by the signal ns and the PMOS transistor 66 is gated by the complementary signal bshift. The drain side of the transistor pair 64 and 66 effects the signal nsout which is coupled through a CMOS pair 68 to produce the scan out signal sout. In addition, the signal nsout is coupled to V_{DD} through a PMOS transistor which is gated by signal sout, and is also coupled to GND through a series connected pair of NMOS transistors 72 and 74, the transistor 72 being gated by the signal sout and the transistor 74 being gated by bshift.

The foregoing described part of the scan latch circuit of FIG. 3 permits scanning in of a test date pattern. For example, test date presented to the scan input port sin is shifted to the center section as signals sd0 and sd1 via transistor pair 48, 50 when SHIFT changes state, and then, shifted to the scan output port sout via transistor pair 64, 66 when SHIFT changes back to its static state. In this manner, serial test data may be shifted through the scan latches of the chain until all of the scan latches have the proper test data stored as sd0 and sd1. The test data stored in the latches may be written to their corresponding functional latches over signal lines fb and in1 using the scan latch circuitry which will now be described.

Referring again to FIG. 3, the signal lines fb and in1 are coupled to GND through respective pairs of NMOS transistors 80, 82 and 84, 86. The transistors 84 and 80 are gated by the signals sd0 and sd1, respectively, and the transistors 82 and 86 are both gated by the WRITE signal. Thus, the test data stored in the scan latch 20 as sd0 and sd1 may be transferred to the signal lines in1 and fb coupled to the functional latch 22 when the WRITE signal changes state. Thereafter, the test data over signal lines fb and in1 may be captured and stored by the functional latch 22 when WRITE is asserted.

In addition, with the WRITE signal in the dormant state, the logic states of signal lines fb and in1 are controlled by the logic state of the functional latch 22 and may be sampled (observed) by the scan latch 20. More specifically, when the signal UPDATE is pulsed, the logic states of lines in1 and fb are transferred to signals sd0 and sd1 via transistors pairs 56, 58 and 60, 62, respectively. The signals sd0 and sd1 control the logic state of sd2 which is transferred to the scan output port via transistor pair 64, 66 and CMOS pair 68. The sampled or observed resultant data from the functional latch 22 may be shifted serially back to the TAP controller 10 in the same manner as described above for scanning in data to the scan latches. The TAP controller 10 may analyze the response data to determine if a failure or failures have occurred.

The exemplary level sensitive functional latch circuit of FIG. 4 is also comprised of NMOS and PMOS transistors as well as complementary metal oxide semiconductor (CMOS) transistor pairs. All of the CMOS pairs of the circuit are coupled between the supply buses V_{DD} and ground GND. Referring to FIG. 4, the latch clock NCK drives a CMOS pair 88 to produce the complementary signal NCK bar. The data input at port 24 is coupled through the channels of a pair of PMOS and NMOS gates 90 which are coupled drain to drain and source to source. The pair of gates 90 are driven by the latch clock NCK and its complement NCK bar. The common drain connections of the gates 90 is coupled to a CMOS pair 92 which produces the complement thereof at the output O, and also coupled to the fb signal line through another CMOS pair 93. The common drains of 90 are also coupled to: (1) the in1 signal line, (2) GND through a pair of series connected NMOS gates 94 and 96, gate 94 being driven by NCK bar and gate 96 being driven by the signal line fb, and (3) V_{DD} through a PMOS gate 98 which is driven by the output of the CMOS pair 93 or the signal line fb.

In operation, when the clock NCK goes high, the latch is “open”, i.e. the input data at port 24 is passed by gates 90 to line 91 of the latch. When the clock NCK goes low, the gates 90 are “closed”, i.e. the input data at port 24 will have no effect on the output O of the latch. Whatever data is on line 91 will be transferred to the output O through the CMOS pair 92. The stored data and its complement may be observed by the scan latch over the signal lines in1 and fb, respectively. When NCK is low, data may be stored into the latch through the in1 and fb signal lines, and transferred to the output through the CMOS pair 92. Note that if the latch clock NCK goes high, then input data at port 24 will overwrite the data on signal lines in1 and fb.

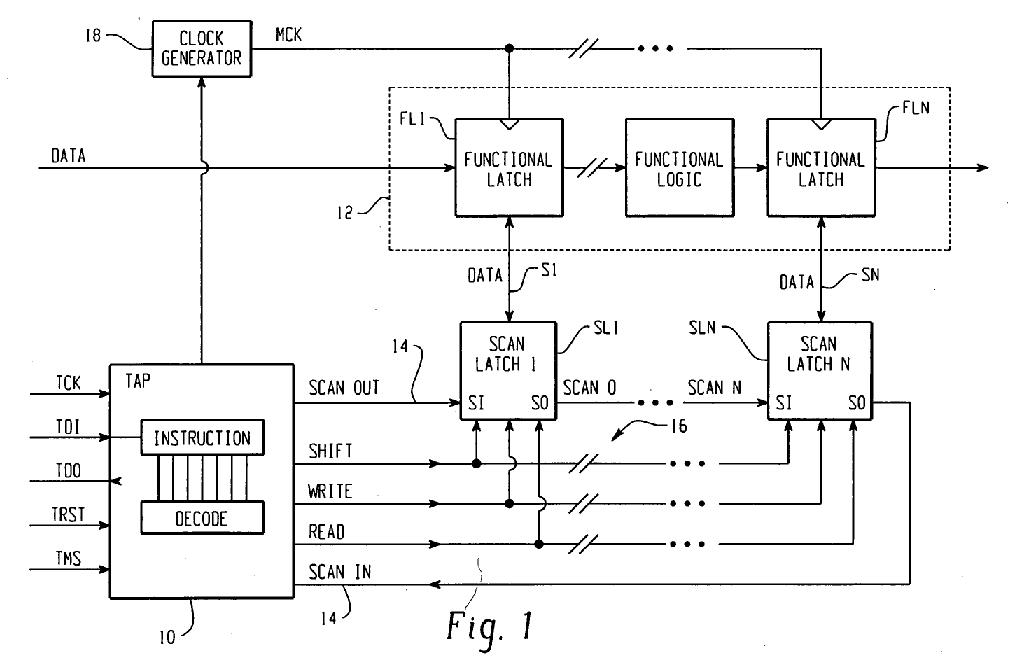

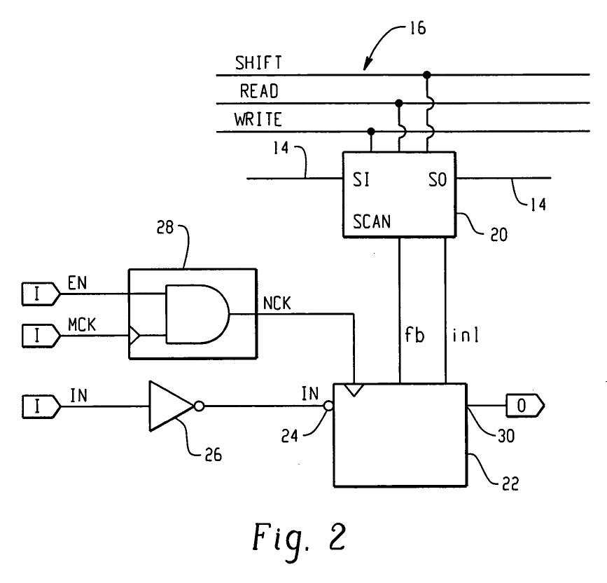

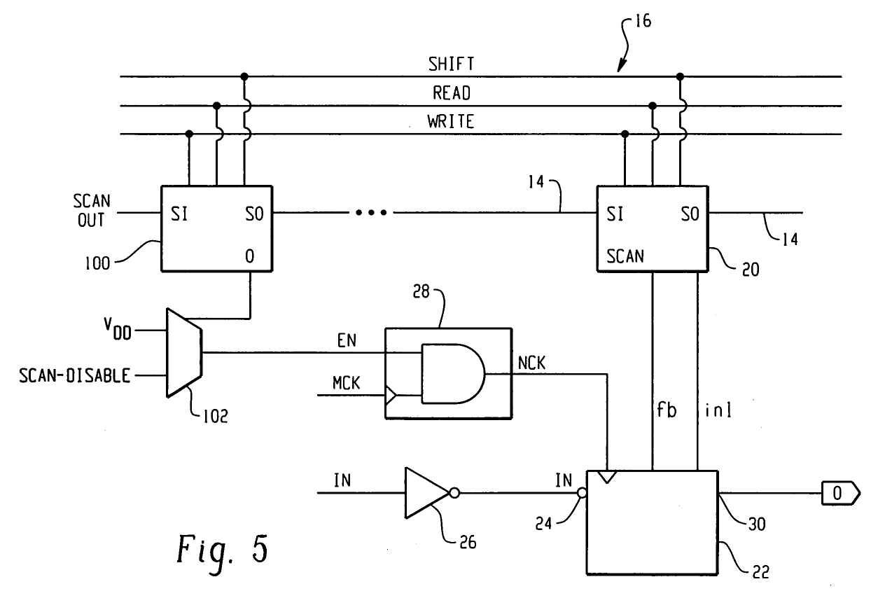

FIG. 5 is a block diagram schematic of an exemplary scannable latch 20,22 for scan chain testing of a functional logic unit. Many of the system components of FIG. 5 remain the same as described for the exemplary system of FIGS. 1 and 2. Thus, the reader can rely on the same reference identifiers and description provided herein above for those common system components. Referring to FIG. 5, a scan mode latch 100 may be added to the system to control the selection input of a signal multiplexer MUX 102. The scan mode latch 100 may be of the scannable type described in connection with the embodiments of FIGS. 2, 3 and 4 for example. The output of the MUX 102 may be coupled to the enable (en) input of the clock driver circuit 28 of one or more scannable latch of the test scan chain (see FIG. 1). The MUX 102 may include two inputs, one input being coupled to the V_{DD} supply and the other coupled to a SCAN_DISABLE signal which has been described above as the signal which is set logically low when data is being scanned via serial bus 14 into or through the plurality of scan latches.

The output O of the scan mode latch 100, which may be the output of the functional latch portion thereof, for example, controls the selection of which input is coupled to the output of the MUX 102, i.e. between V_{DD} and SCAN_DISABLE, for example. In one embodiment, the scan mode latch 100 may be coupled to and controlled by the TAP controller 10 using the scan out, Write (W) and Shift (Sh) signal lines thereof. To reduce the number of signal lines distributed through the integrated circuit, the scan mode latch 100 may be part of the associated scan chain (see FIG. 1). In a typical set up operation of the scan mode latch 100, the TAP controller 10 may present the desired bit status on the scan out line coupled to the SI input of the scan mode latch 100 and scan it into the scan latch 20 thereof by pulsing the Shift signal. Thereafter, the Write (W) signal may be toggled to provide the desired bit status over the fb and in1 lines to the output of the functional latch portion of the latch 100. The bit status set up at the output of the latch 100 will control the input selection of the MUX 102.

Referring to FIG. 5, when the MUX 102 is controlled to select the V_{DD} input, V_{DD} is applied to the en input of the clock driver circuit 28 of the scannable latch. In this mode, the latch clock NCK continues operating the latch 22 of the scannable latch to capture data from port 24, thus allowing the data of the scannable latch to be updated and scanned into the TAP controller 10 via signal lines fb and in1 of scan latch 20 from time to time by the test scan chain. Thus, this mode renders the data of the scannable latches observable.

Moreover, when the MUX 102 is controlled to select the SCAN_DISABLE input which has been set to a low state, the SCAN_DISABLE signal is applied by the MUX 102 to the en input of the clock driver circuit 28 of the scannable latch. In this mode, the latch clock NCK is disabled and held low by circuit 28 during test data scan as described supra. Consequently, test data may be scanned and written into the scannable latch without being disturbed by data at the input port 24 thereof. This mode renders the output 30 of the scannable latch controllable via signal lines fb and in1 of scan latch 20.

Before a scan chain test may be executed, the scan mode latch 100 is set up, as described supra, to control the MUX 102 to provide the proper signal to the input en of the clock driver circuit 28 of the scannable latch of the scan chain. For example, the TAP controller 10 knows the scan chain operation that it is about to perform. Thus, prior to performing a controllable or observable operation, it will set up the scan mode latch 100 to control the MUX 102 to select the proper signal, i.e. V_{DD} or SCAN_DISABLE, to apply to the clock driver circuit 28 of the scannable latch. In the present embodiment, a logic low at the output O of the latch 100 will control the MUX 102 to select the V_{DD} signal and thus, render the scannable latch in the observable mode. Conversely, a logic high at the output O of the latch 100 will control the MUX to select the SCAN_DISABLE signal and thus, render the scannable latch in the controllable mode. Note that SCAN_DISABLE may be set low prior to the selection thereof.

Generally, for a scan chain test as will be described in greater detail below, a test data pattern is initially scanned and written into a plurality of scannable latches designated as input test data latches by the TAP controller 10 via the serial bus 14 and Shift and Write signals of the control bus 16. So, prior to this controllable operation, the TAP controller 10 will set up the scan mode latch 100 to output a logic high to the MUX 102 to control selection of the SCAN_DISABLE signal (set logical low) thereby. As noted above, the signal SCAN_DISABLE is a signal which supports fault testing methodologies, like automated test pattern generation (ATPG), for example. In the present embodiment, the signal SCAN_DISABLE is low during ATPG which disables the latch clock NCK of the designated plurality of input scannable latches. With the latch clock NCK disabled and held low, test data may be written into the plurality of scannable latches and preserved for the test cycle without being overwritten by input data as described supra.

Then, one or more scannable latches may be designated by the TAP controller 10 as latches for use in observing the resultant test data of the logic unit 12. Prior to the test cycle for the test data pattern which is an observable operation, the TAP controller 10 will set up the scan mode latch associated with the observable latches to output a logic low to the MUX to control selection of the V_{DD} signal. In this observable mode, the latch clock NCK continues to be responsive to the clock MCK to operate the designated observable latches to respond to the test data pattern. Resultant test data may be updated from time to time from the designated observable latches and scanned into the TAP controller 10 for analysis.

Controlling the operational modes of the scannable latches with a scan mode latch 100, such as described herein above, may be considered risky because during power start-up, the bit status of the output of the scan mode latch 100 is unknown. However, in the present embodiment, during power start-up, the SCAN_DISABLE signal is guaranteed to be at the same voltage potential as V_{DD}, i.e. logic high. So, at power start-up, the output of the MUX 102 will be at the same voltage potential independent of the selection bit status of the scan mode latch 100. After power start-up and before a scan chain test is performed, the scan mode latch 100 will be set up to the proper mode as described supra.

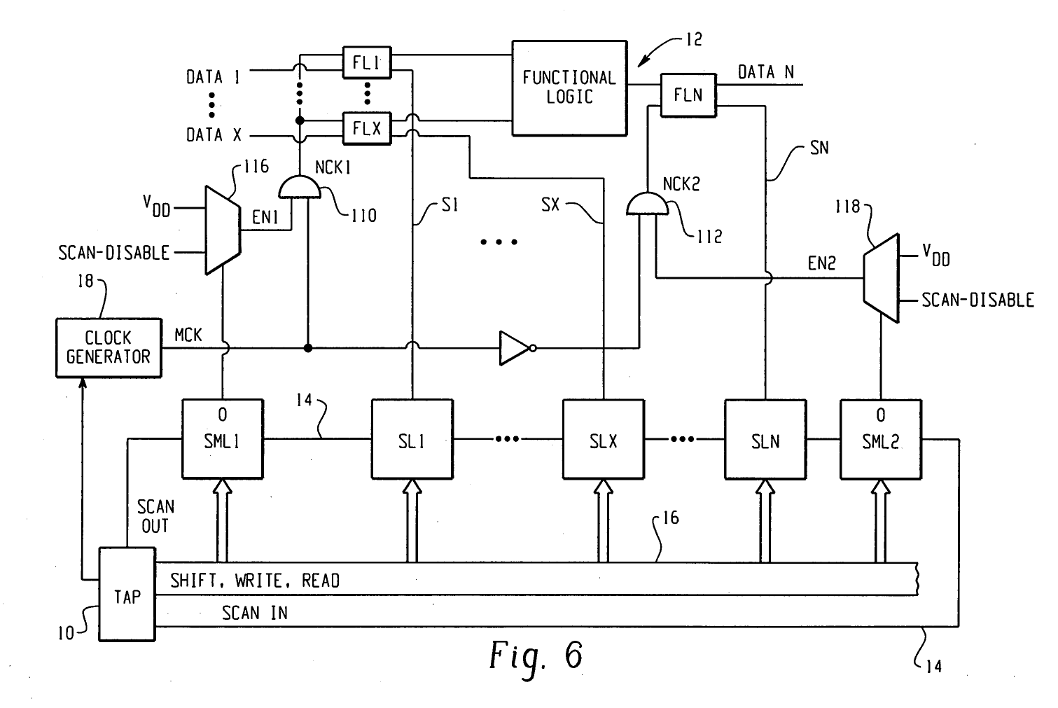

FIG. 6 is a block diagram schematic of an exemplary system for scan chain testing of a functional logic unit 12 suitable for embodying another aspect of the present invention. The system embodiment of FIG. 6 applies the concept of controlling the test modes of a scannable latch described in connection with the embodiment of FIG. 5. FIG. 6 includes components common to the system of FIG. 1. Such common components have been given reference numerals and described in connection with the system of FIG. 1. Thus, there is no reason to change the reference numerals of these common components nor offer a redundant description thereof.

In the embodiment of FIG. 6, the scan latches SL1, . . . , SLN may be part of a test scan chain for testing the logic unit 12. A plurality of functional latches FL1, . . . , FLX may be designated by the TAP controller 10, for example, to control input test data to the logic unit 12 via their respectively corresponding scan latches SL1, . . . , SLX. Also, at least one functional latch FLN may be designated by the TAP controller 10 to observe resultant test data from the logic unit 12 via its corresponding scan latch SLN. A latch clock NCK1 derived from the clock MCK via a clock driver 110 is used to clock the data input latches FL1, . . . , FLX. Likewise, a latch clock NCK2 derived from an inverted clock signal MCK (bar) via clock driver 112 is used to clock the data output latch FLN.

The system of FIG. 6 further includes scan mode latches SML1 and SML2 as part of the test scan chain, for example. The SML1 is controlled by the TAP controller 10 via serial bus 14 and control signals of bus 16 to set up the signal selection of a signal MUX 116 to be the enable signal en1 for the clock driver 110 as described herein above in connection with the embodiment of FIG. 5, for example. The SML2 is controlled in the same or similar manner as SML1 to set up the signal selection of a signal MUX 118 to be the enable signal en2 for the clock driver 112. The TAP controller 10 is also operative to halt and then, toggle the master clock signal MCK via the clock generator 18. The clock MCK may be distributed to the various system components as described supra to synchronize the operations thereof.

In a typical scan chain test of the logic unit 12 using the system of FIG. 6, data may be provided over the serial bus 14 to set up the scan mode latches SML1 and SML2 for the proper test control modes. For example, the SML1 should be set up to control input data latches FL1, . . . , FLX to accept input test data. That is, the output of SML1 is set up to select SCAN_DISABLE (which is set low) as the en1 signal to the clock driver 110 to disable and hold low the latch clock NCK1. In this state, test data may be scanned into the scan latches SL1, . . . , SLX and written to their respectively corresponding latches FL1, . . . , FLX via S1, . . . , SX, respectively. Since the latch clock NCK1 is held low, the input data to the logic unit 12 from the input data latches will be the test data and not the functional data over lines DATA1, . . . , DATAX. Thus, the latches FL1, . . . , FLX are controllable.

Likewise, the output of SML2 is set up to select V_{DD} as the en2 signal to the clock driver 112 to enable the latch clock NCK2 to be responsive to the clock MCK. Next, the TAP controller 10 may halt and then, pulse MCK from high to low to high, for example. Since, the clock driver 110 is disabled by the proper setting of en1, the pulse of MCK will have no effect on the input data latches. Also, since the clock driver 112 is enabled by the proper setting of en2, it will respond to the inverted pulse of MCK to generate a pulse over NCK2 to clock into latch FLN the resultant test data output (DATA N) from the logic unit 12. Thereafter, the TAP controller 10 may read via signal line SN the corresponding scan latch SLN with the resultant test output data captured by FLN and scan it in over the serial bus 14 for a comparison with a reference copy of the results, for example.

The embodiment of FIG. 6 pre-designated certain scannable latches of a scan chain as input data latches and output data latches and associated a scan mode latch and MUX with each grouping. However, it is understood that this is merely an exemplary system embodiment of numerous combinations and possibilities to which the inventive concept may be applied. The inventive concept may even be applied to a system in which a scan mode latch and MUX may be fabricated on the integrated circuit for each scannable latch of a scan chain. In such an embodiment, each scannable latch may be designated individually by the TAP controller, for example, to be either controllable or observable depending on the test criteria.

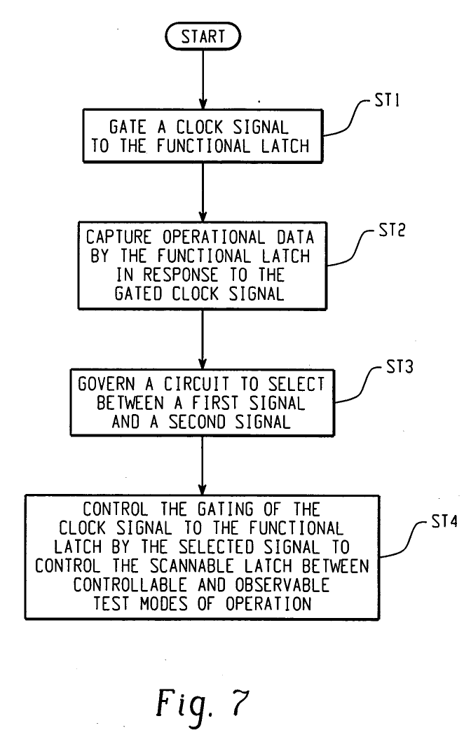

In view of the above, it will be understood that one embodiment of a method of controlling an operational test mode of a scannable latch in a test scan claim, wherein the scannable latch comprises the scan latch 20 and the functional latch 22 coupled thereto as shown schematically in the embodiment of FIG. 5, may be as illustrated in the exemplary flowchart of FIG. 7. The method may comprise the steps of: ST1—gating a clock signal to the functional latch; ST2—capturing operational data by the functional latch in response to the gated clock signal; ST3—governing a circuit to select between a first signal and second signal; and ST4—controlling the gating of the clock signal to the functional latch by the selected signal to control the scannable latch between controllable and observable test modes of operation. Additional and/or alternative steps may be added to the method as set forth in detail above with reference to certain specific, non-limiting embodiments.

While the present invention has been presented herein above in connection with one or more embodiments, it is understood that all such embodiments were described merely by way of example with no intention of limiting the invention in any way. Accordingly, the present invention should not be limited by any of the presented embodiments, but rather construed in breadth and broad scope in accordance with the recitation of the claims appended hereto.

What is claimed is:

1. Apparatus for controlling an operational test mode of a scannable latch in a test scan chain, said scannable latch comprising a scan latch and a functional latch coupled thereto, said apparatus comprising:
first circuit for gating a clock signal to said functional latch, said functional latch being responsive to said gated clock signal to capture operational data, said first circuit including an input for controlling the gating operations thereof; and
second circuit governed by a selection signal to apply a selected one of a first signal and second signal to said input of said first circuit to control said scannable latch between controllable and observable test modes of operation.

2. The apparatus of claim 1 wherein when the first signal is applied to the input of the first circuit, the gating of the clock signal to the functional latch is disabled rendering the scannable latch in a controllable test mode which permits the scan latch to control output data of the functional latch; and wherein when the second signal is applied to the input of the first circuit, the gating of the clock signal to the functional latch is enabled rendering the scannable latch in an observable mode which permits the scan latch to observe the captured data of the functional latch.

3. The apparatus of claim 2 wherein the first circuit comprises a logic gate including one input coupled to the clock signal and another input coupled to the selected one of the first and second signals for controlling the gating of the clock signal to the functional latch.

4. The apparatus of claim 2 wherein the first circuit comprises a clock driver circuit of the scannable latch.

5. The apparatus of claim 1 wherein the second circuit comprises a signal multiplexer circuit governed by the selection signal and including first and second inputs coupled to the first and second signals, respectively, and an output coupled to the input of the first circuit.

6. The apparatus of claim 1 including a scan mode latch circuit settable to generate the selection signal which governs the selection of the second circuit between the first and second signals.

7. The apparatus of claim 6 wherein the scan mode latch circuit comprises a scan mode scannable latch.

8. The apparatus of claim 7 wherein the scan mode scannable latch includes a scan latch coupled to a functional latch; and wherein said scan latch is governed by a set of scan chain control signals to scan in and write the selection signal to an output of said functional latch, which output being coupled to the second circuit.

9. The apparatus of claim 8 wherein the scan mode scannable latch includes a scan mode gate circuit controllably operative to pulse said functional latch to capture said selection signal from the scan latch coupled thereto.

10. Method of controlling an operational test mode of a scannable latch in a test scan chain, said scannable latch comprising a scan latch and a functional latch coupled thereto, said method comprising the steps of:
gating a clock signal to said functional latch;
capturing operational data by said functional latch in response to said gated clock signal;
governing a circuit to select between a first signal and second signal; and
controlling the gating of the clock signal to said functional latch by said selected signal to control said scannable latch between controllable and observable test modes of operation.

11. The method of claim 10 including the steps of disabling the gating of the clock signal to the functional latch by the first signal to render the scannable latch in a controllable test mode which permits the scan latch to control output data of the functional latch; and enabling the gating of the clock signal to the functional latch by the second signal to render the scannable latch in a observable mode which permits the scan latch to observe the captured data of the functional latch.

12. The method of claim 10 wherein the circuit is governed by a selection signal to select between the first and second signals.

13. The method of claim 12 wherein a signal multiplexer circuit is governed by a selection signal to select between the first and second signals.

14. The method of claim 12 including setting a scan mode latch circuit to generate the selection signal which governs the selection of the circuit between the first and second signals.

15. The method of claim 12 including the step of setting includes: scanning the selection signal into the scan mode latch circuit; controlling the scan mode latch circuit to capture the scanned in selection signal; and applying the captured selection signal to the circuit.

15. The method of claim 14 wherein the step of setting includes governing the scan mode latch circuit by a set of scan chain control signals to scan in and capture the selection signal for governing the circuit.

16. The method of claim 15 including applying a pulse to the scan mode latch circuit to capture the scanned in selection signal.

17. System for scan chain testing an electrical unit, said system comprising:
a plurality of scannable latches coupled to said electrical unit, each scannable latch of said plurality including a scan latch coupled to a functional latch of said electrical unit, said plurality of scan latches being configured in a test scan chain;
first circuit for setting a first subset of said plurality of functional latches in a controllable test mode, each functional latch of said first subset being responsive to input test data from corresponding scan latches to test said electrical unit; and
second circuit for setting a second subset of said plurality of functional latches in an observable test mode, each functional latch of said second subset being responsive to resultant test data from said electrical unit and operative to update the corresponding scan latch with said observed resultant test data.

18. The system of claim 17 wherein each of said first and second circuits includes a settable scan mode latch circuit.

19. The system of claim 18 wherein each scan mode latch circuit is settable by a set of scan chain control signals.

20. The system of claim 17 wherein each first and second circuit comprises:
third circuit for gating a clock signal to each of said associated functional latches, each associated functional latch being responsive to said gated clock signal to capture operational data, said first circuit including an input for controlling the gating operations thereof; and
fourth circuit governed by a selection signal to apply a selected one of a first signal and second signal to said input of said third circuit to control the functional latches of the associated subset to one of the controllable and observable test modes of operation.

21. Apparatus for controlling an operational test mode of a scannable latch in a test scan chain, said scannable latch comprising a scan latch and a functional latch coupled thereto, said apparatus comprising:
first means for gating a clock signal to said functional latch, said functional latch being responsive to said gated clock signal to capture operational data, said first means including an input for controlling the gating operations thereof; and
second means for applying a selected one of a first signal and second signal to said input of said first means to control said scannable latch between controllable and observable test modes of operation.

22. System for scan chain testing an electrical unit, said system comprising:
a plurality of scannable latches coupled to said electrical unit, each scannable latch of said plurality including a scan latch coupled to a functional latch of said electrical unit, said plurality of scan latches being configured in a test scan chain;
first means for setting a first subset of said plurality of functional latches in a controllable test mode, each functional latch of said first subset being responsive to input test data from corresponding scan latches to test said electrical unit; and
second means for setting a second subset of said plurality of functional latches in an observable test mode, each functional latch of said second subset being responsive to resultant test data from said electrical unit and operative to update the corresponding scan latch with said observed resultant test data.
